(19) United States
(12) Patent Application Publication
(10) Pub. No.: US 2023/0213869 A1
(43) Pub. Date: Jul. 6, 2023

(54) Three-Dimensional Micro-Nano Morphological Structure Manufactured by Laser Direct Writing Lithography Machine, and Preparation Method Therefor

(71) Applicants: SVG TECH GROUP CO., LTD, Suzhou, Jiangsu (CN); SOOCHOW UNIVERSITY, Suzhou, Jiangsu (CN)

(72) Inventors: Linsen CHEN, Suzhou, Jiangsu (CN); Donglin PU, Suzhou, Jiangsu (CN); Jin ZHANG, Suzhou, Jiangsu (CN); Ming ZHU, Suzhou, Jiangsu (CN); Pengfei ZHU, Suzhou, Jiangsu (CN); Wen QIAO, Suzhou, Jiangsu (CN); Haoshu ZHU, Suzhou, Jiangsu (CN); Xiaoning LIU, Suzhou, Jiangsu (CN); Renjin SHAO, Suzhou, Jiangsu (CN); Ying YANG, Suzhou, Jiangsu (CN)

(21) Appl. No.: 18/015,852

(22) PCT Filed: Jan. 19, 2022
(86) PCT No.: PCT/CN2022/072747

§ 371 Date: Jan. 12, 2023

(30) Foreign Application Priority Data
Mar. 12, 2021 (CN) 202110270751.5

(51) Int. Cl. G03F 7/20

(52) U.S. Cl. CPC G03F 7/705; G03F 7/70425; G03F 7/70383; G03F 7/70508

(57) ABSTRACT

A preparation method (100) for a three-dimensional micro-nano morphological structure manufactured by a laser direct writing lithography machine, comprising: step 110, providing a three-dimensional model diagram; step 120, dividing the three-dimensional model diagram in a height direction to obtain at least one height interval; and step 130, projecting the three-dimensional model diagram onto a plane to obtain a mapping relationship, wherein the mapping relationship comprises coordinates, on the plane, corresponding to each point on the three-dimensional model diagram, and wherein the height of each point on the three-dimensional model diagram corresponds to a height value in a corresponding height interval; and making the mapping relationship correspond to an exposure dose according to the mapping relationship, and performing lithography on the basis of the exposure dose. Any three-dimensional micro-nano morphological structure can be obtained. Further disclosed is a three-dimensional micro-nano morphology structure manufactured by a laser direct writing lithography machine.

### FIELD OF THE PRESENT DISCLOSURE

The present invention relates to the field of lithography, and more particularly to a three-dimensional micro-nano morphological structure manufactured by laser direct writing lithography machine, and a preparation method therefor.

### BACKGROUND OF THE PRESENT DISCLOSURE

At present, the main technical means of micromachining are precision diamond turning, 3D printing, lithography, etc. Diamond turning is a preferred method for manufacturing tens of micron-sized, regularly aligned 3D morphological microstructures, its typical application being micro-prism film. 3D printing technology can manufacture complex 3D structures, but the resolution of the traditional galvanometer scanning 3D printing technology is tens of microns; the resolution of DLP projection 3D printing is 10-20 μm, two-photon 3D printing technology has sub-micron resolution but is a serial processing mode with very low efficiency.

Microlithography technology is still the mainstream technical means of modern micromachining, and is also the highest precision processing means so far. 2D projection lithography has been widely used in the field of microelectronics. 3D morphological lithography technology is still in its infancy, and no mature technical solution has been formed, and the current progress is as follows.

The traditional mask overlay method is used to make a multi-step structure, combining with ion etching to control the depth of the structure. The process requires multiple alignments, having high process requirements, and it is difficult to process continuous 3D morphology. For a grey scale mask exposure method, the technical solution thereof is to make a half-tone mask, generate a grey scale distribution transmission light field after the irradiation by a mercury lamp light source, and perform sensitization on a photoresist to form a 3D surface structure. However, such masks are difficult to make and have a very expensive price. With the moving mask exposure method, regular micro-lens array and other structures can be manufactured. An acousto-optic scanning direct writing method (e.g., Heidelberg instrument μPG101) uses single beam direct writing has lower efficiency, and still has the problem of pattern stitching. Electron beam grey scale direct writing (Japan Joel JBX9300, Germany Vistec, Leica VB6) still has low preparation efficiency for devices having a large area and thus is limited by the energy of electron beams. 3D morphology has insufficient depth regulating and control capability and is thus suitable for preparing small-scale 3D morphological microstructures. The digital grey scale lithography technology is a micro-nano processing technology that combines grey scale mask and digital optical processing technology. The DMD (Digital Micro-mirror Device) spatial light modulator is used as a digital mask to produce a relief microstructure of a continuous three-dimensional surface shape through one exposure. A pattern larger than one exposure field uses the step-by-step splicing method. The research group also used this method to do experimental research. The main disadvantage is that the grey scale modulation capability is limited by the grey level of DMD, has a step shape and the field is stitched, and the uniformity of light intensity inside the light spot affects the face type quality of 3D morphology.

In conclusion, there is a significant gap between the research status of 3D morphology lithography and the demand for the leading edge. Therefore, the research of high-quality lithography technology that can realize random 3D morphology has become an important and urgent demand for microlithography technology in the related field.

The application of a roll-to-roll imprinting apparatus in flexible printed circuits presents another problem that is difficult to overcome. Since the flexible printed circuit has flexibility, it is difficult to precisely control the tension or tensile degree of the flexible printed circuit, which makes it difficult to perform alignment in subsequent processes such as exposure, etching or alignment and fitting. In the prior art, a tension roller is usually used to detect the tension or tensile degree of the flexible printed circuit; however, the current tension roller has problems such as insufficient detection accuracy, and the control of the tension or tensile degree of the flexible printed circuit cannot meet the requirements of normal industrial production.

### SUMMARY OF THE PRESENT DISCLOSURE

It is an object of the present invention to provide a three-dimensional micro-nano morphological structure manufactured by a laser direct writing lithography machine, and a preparation method therefor, which can easily manufacture any three-dimensional micro-nano morphological structure with high quality.

To achieve the object of the present invention, according to one aspect of the present invention, there is provided a preparation method for a three-dimensional micro-nano morphology structure manufactured by a laser direct writing lithography machine, comprising: providing a three-dimensional model diagram; dividing the three-dimensional model diagram in a height direction to obtain at least one height interval; and projecting the three-dimensional model diagram onto a plane to obtain a mapping relationship, wherein the mapping relationship comprises coordinates, on the plane, corresponding to each point on the three-dimensional model diagram, and wherein a height of each point on the three-dimensional model diagram corresponds to a height value in a corresponding height interval; and making the mapping relationship correspond to an exposure dose according to the mapping relationship, and performing lithography on the basis of the exposure dose.

According to another aspect of the present invention, there is provided a three-dimensional micro-nano morphological structure manufactured by a laser direct writing lithography machine, comprising: a substrate; and at least one three-dimensional micro-nano morphological unit formed on the substrate, wherein each three-dimensional micro-nano morphological unit comprises at least one visual high point, and each three-dimensional micro-nano morphological unit comprises multiple annuli, wherein a slope of a slope morphology in the annuli changes according to a preset rule starting from a visual high point.

Compared with the prior art, according to the preparation method for a three-dimensional micro-nano morphological structure manufactured by a laser direct writing lithography machine in the present invention, a mapping relationship is obtained by projecting a three-dimensional model diagram on a plane, and according to the mapping relationship, lithography is performed by correlating the mapping relationship and an exposure dose so as to obtain a random three-dimensional micro-nano morphological structure. At the same time, the three-dimensional micro-nano morphological structure of the present invention can make a very vivid stereoscopic vision on a plane, giving a very good visual experience.

### BRIEF DESCRIPTION OF THE DRAWINGS

FIG. 1 is a schematic view showing a structure of a preparation method for a three-dimensional micro-nano morphological structure according to a first embodiment of the present invention.

FIG. 2a, FIG. 2b, and FIG. 2c are schematic views of a first application example of the preparation method in FIG. 1.

FIG. 3 is a schematic view of a second application example of the preparation method in FIG. 1.

FIG. 4 is a schematic view showing a structure of a preparation method for a three-dimensional micro-nano morphological structure according to a second embodiment of the present invention.

FIG. 5 is a first application example of the preparation method in FIG. 4.

FIG. 6 is a second application example of the preparation method in FIG. 4.

FIG. 7 is an example of a three-dimensional micro-nano morphological structure manufactured by a preparation method for a three-dimensional micro-nano morphological structure according to the present invention.

FIG. 8 is a microscopic schematic view of the three-dimensional micro-nano morphological structure in FIG. 7.

FIG. 9 is one example of a three-dimensional model diagram according to the present invention.

FIG. 10 is one example of a surface of a three-dimensional model diagram according to the present invention.

FIG. 11 is a collapsed Fresnel structure.

FIG. 12 illustrates one embodiment of a lithographic apparatus of the present invention.

FIG. 13 illustrates one embodiment of a nano-imprinting device of the present invention.

### DESCRIPTION OF THE EMBODIMENTS

To further illustrate the technical means and effects of the present invention for achieving the predetermined object of the invention, a detailed description of specific implementation modes, structures, features, and effects according to the present invention is described below with reference to the accompanying drawings and preferred embodiments.

### The First Embodiment

FIG. 1 is a schematic view showing a structure of a preparation method for a three-dimensional micro-nano morphological structure manufactured by a laser direct writing lithography machine according to the first embodiment of the present invention. The preparation method 100 for the three-dimensional micro-nano morphological structure uses a laser direct writing lithography machine, which includes the following steps.

Step 110, providing a three-dimensional model diagram.

In one embodiment, providing a three-dimensional model diagram includes: the three-dimensional model diagram including at least one three-dimensional model unit, setting at least one curvature value to the three-dimensional model unit, and determining the height of a point in the three-dimensional model diagram based on the curvature value.

In another embodiment, providing a three-dimensional model diagram includes the following: fitting the surface of the three-dimensional model diagram by splicing multiple spatial polygons, wherein each of the spatial polygons is a convex polygon, each of the spatial polygons does not overlap with each other, each of the spatial polygons has a determined vertex and side, and a height range of the three-dimensional model diagram at the polygon position is determined according to the vertex of the spatial polygon and the normal vector of the plane where the spatial polygon is located.

Step 120. Dividing the three-dimensional model diagram in a height direction to obtain at least one height interval.

Step 130. Projecting the three-dimensional model diagram onto a plane to obtain a mapping relationship, wherein the mapping relationship comprises coordinates, on the plane, corresponding to each point on the three-dimensional model diagram, and wherein the height of each point on the three-dimensional model diagram corresponds to a height value in a corresponding height interval, and making the mapping relationship correspond to an exposure dose according to the mapping relationship, and performing lithography on the basis of the exposure dose.

In one embodiment, projecting the three-dimensional model diagram on a plane to obtain a mapping relationship further comprises: obtaining a grey scale value corresponding to the height value of each point in the mapping relationship by correlating each height interval on the three-dimensional model to a grey scale value range, and obtaining a grey scale image according to the plane coordinate and the height value in the mapping relationship. Lithography can be performed based on the exposure dose by correlating the grey graph to the exposure dose.

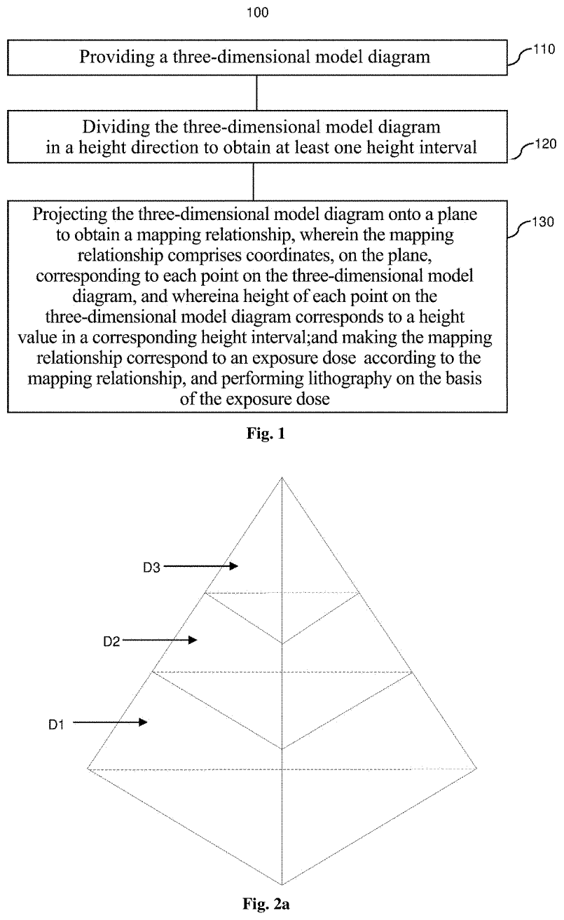

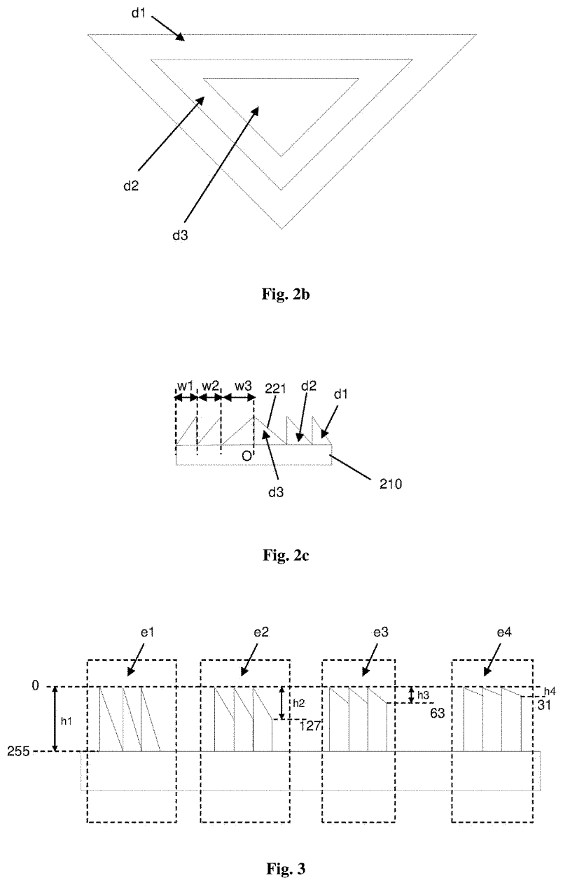

In one embodiment, the height range of each height interval corresponds to the entirety of the grey scale value range. For example, all of the grey scale value ranges are 0-255, then the grey scale value range corresponding to the height range of each height interval is 0-255. As shown in FIGS. 2a-2c, the grey scale value range corresponding to the height interval D1 is 0-255, the grey scale value range corresponding to the height interval D2 is also 0-255, and the grey scale value range corresponding to the height interval D3 is also 0-255. In one alternative embodiment, the height range of one or more height intervals corresponds to a part of the grey scale value range, and the height range of the remaining one or more height intervals corresponds to the whole of the grey scale value range, the part of the grey scale value range being X1 to X2. For example, X1 may be 0, and X2 may be 128. That is to say, the grey scale value range corresponding to the height ranges of some height intervals may be 0-128, and the grey scale value range corresponding to the height ranges of some height intervals may be 0-255; of course, X2 may also be 64, 32, etc. As shown in FIG. 3, the grey scale value range corresponding to the height ranges of some height intervals is 0-255, the grey scale value range corresponding to the height ranges of some height intervals is 0-128, the grey scale value range corresponding to the height ranges of some height intervals is 0-64, and the grey scale value range corresponding to the height ranges of some height intervals is 0-32.

In one embodiment, each height interval has the same height difference, e.g., the total height of the three-dimensional model diagram is 3 mm and the height difference of each height interval is 20 μm so that it can be divided into a total of 3 mm/20 μm=150 height intervals. In one alternative embodiment, the height intervals have different height differences, e.g., some height intervals having a height difference of 10 μm, some height intervals having a height difference of 30 μm, etc.

In one embodiment, the correspondence between the height range of each height interval and the corresponding part or all of the grey scale value ranges is a linear correspondence. For example, the height difference of one height interval is 20 μm, the corresponding grey scale value range is 0-255, the grey scale value corresponding to the lowest point of the height interval is 0, the grey scale value corresponding to the highest point of the height interval is 255, the grey scale value corresponding to the middle point of 10 μm of the height interval is 127, and the grey scale values corresponding to the other middle points of the height interval are in direct proportion to the height values of the same. In one alternative embodiment, the correspondence between the height range of each height interval and the corresponding part or all of the grey scale value ranges is a curve correspondence.

In one embodiment, the grey scale image may be segmented into multiple unit images followed by lithography to form a slope morphology on a target carrier. Specifically, the higher the grey scale value of the pixel point of the grey scale image is, the longer the corresponding lithography time is, the greater the exposure dose is, and the deeper the lithography can be performed; the lower the grey scale value of the pixel point of the grey scale image is, the shorter the corresponding lithography time is, the smaller the exposure dose is, and the shallower the lithography can be performed, and thus the slope morphology of various shapes can be lithographed. Of course, in an altered embodiment, it is also possible that the lower the grey scale value of the pixel point of the grey scale image is, the longer the corresponding lithography time is, the greater the exposure dose is, and the deeper the lithography can be.

Several application examples of the preparation method 100 for a three-dimensional micro-nano morphological structure are described below.

Application example 1. The height of the three-dimensional model is 3 mm and the height difference of the height interval is 20 μm. Then it is divided into a total of 3 mm/20 μm=150 height intervals. Then there are 150 sets of loop lines in the projected grey scale image, the grey range is 0-255, and the grey scale value between two loop lines in the 150 sets of loop lines varies linearly from 0 to 255. The resulting grey scale image is cut to a size that can be displayed by DMD and lithography is performed. At this time, because isometry segmentation is performed on the height, the period between two loop lines changes, and the slope angle of slope morphology also changes therewith. When all the grey scale values between two loop lines vary linearly from 0 to 255, the depths of the grooves are uniform, and the cross section of the groove is a right triangle. FIG. 2a illustrates a three-dimensional model schematically divided into three height intervals D1, D2, and D3. FIG. 2b is a top view of a three-dimensional micro-nano morphology obtained after lithography, and FIG. 2c is a cross-sectional view of FIG. 2b. As shown in FIG. 2c, the grey scale value of the lowest point of the height interval D1 is 0, i.e., it is not lithographed. The grey scale value of the highest point of the height interval D1 is 255, and the grey scale value of the lowest point of the height interval D1 may also be 255, i.e., it is not lithographed. The grey scale value of the highest point of the height interval D1 is 0 so that one slope morphology d1 is formed by lithography on the target carrier, and a right-angled triangular groove is thus formed.

Application example 2. The height of the three-dimensional model is 3 mm and the height difference of the height interval is 20 μm. Then it is divided into a total of 3 mm/20 μm=150 height intervals. Then there are 150 sets of loop lines in the projected grey scale image. The grey scale value ranges are 0-255, 0-127, 0-63, and 0-31. The corresponding grey scale value between two loop lines in the first 30-loop line set starting from the inside is from 0 to 31, the corresponding grey scale value between two loop lines in the second 30-loop line set is from 0 to 63, the corresponding grey scale value between two loop lines in the third 30-loop line set is 0-127, and the corresponding grey scale value between two loop lines in the last 60-loop line set is 0-255. The obtained grey scale image is cut into a size that can be displayed by DMD, and lithography is performed. Since there are a total of four ranges of the grey scale value, the depth of the groove also has four different depths. Since isometry segmentation is performed on the height, the period w between two loop lines changes, and the slope angle θ of slope morphology also changes therewith. As shown in FIG. 3, the grey scale value range corresponding to part e1 is 0-255, the lithography depth of the same is deeper, and the slope morphology of the same is steeper; the grey scale value range corresponding to part e2 is 0-127, the lithography depth of the same is slightly shallow, and the slope morphology of the same is flatter; the grey scale value range corresponding to part e3 is 0-63, and the grey scale value range corresponding to part e4 is 0-31.

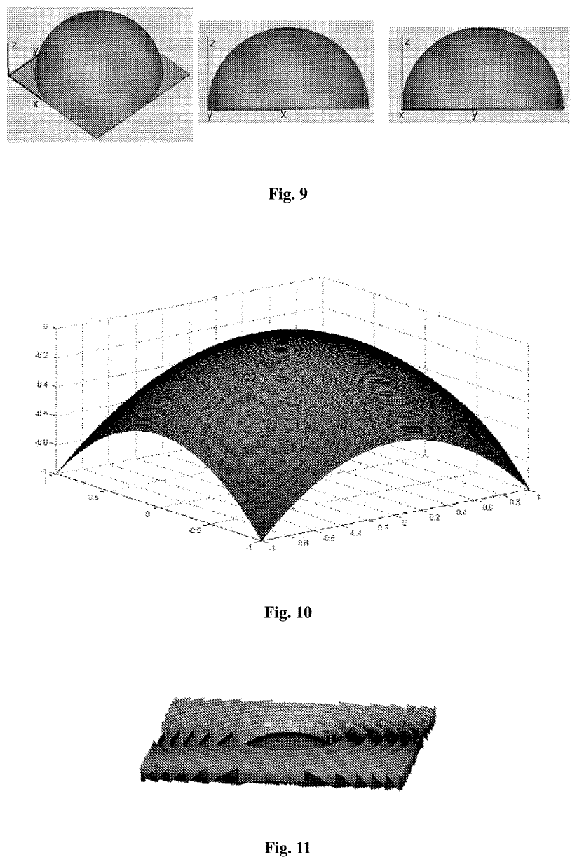

One embodiment of the present invention will be described below with reference to FIGS. 9-11.

As shown in FIG. 9, the three-dimensional model is located in a plane xoy (shown as a hemisphere instead). The surface of the three-dimensional model is meshed into polygons in a limited number of three-dimensional spaces, and the plane where each polygon is located forms a certain included angle with the xoy plane, namely, it can be taken as the inclined angle of the surface of the three-dimensional model at the position. The slope angle formed by the plane where the polygon on the surface of the three-dimensional model is located and the plane xoy has a first included angle θ₁ in the plane xoz. The slope angle formed by the plane where the polygon on the surface of the three-dimensional model is located and the surface xoy has a second inclination angle θ₂ in the plane yoz. The inclined plane parameters (θ₁, θ₂) and pixel position (x, y) of the triangle can completely express the light field information, and realize the control of the emergent ray. The vector height h of the lowest point of the surface of the three-dimensional model may be 0 or may be a height other than 0. The vector height h of the lowest point of the polygonal surface after meshing the three-dimensional model does not affect the exit angle of the emergent light.

When the incident light wave has a wavelength λ that is much smaller than a single pixel size P (such as the side length of the micro prism block) (P≥2λ), its exit direction follows Snell's law:

n1 sin α=n2 sin β

wherein n1 is the refractive index of the incident medium, n2 is the refractive index of the exit medium, and α and β are the incident angle and exit angle of the light ray, respectively.

Therefore, by changing θ₁ and θ₂, it is possible to realize any angle of any position of the surface of the three-dimensional model with respect to a range within a hemisphere along the z-axis of the xoy plane, namely, a plane composed of the normal direction n of the xoy plane and the normal direction n′ of the plane where the triangle in the three-dimensional model is located can rotate one revolution around the normal direction n of the xoy plane, and then regulates and controls the exit angle by using Snell's law formula so as to realize independent regulation and control of two angular variables (θ, φ). In combination with the regulation and control of the pixel position (x, y), and with the addition of the height h of the three-dimensional model at the position, it can realize the independent regulation and control of five variables and realize the control of emergent light.

In order to achieve a 3D optical effect, these five variables need to be controlled to realize the control of the emergent light. The surface of the designed three-dimensional model is meshed to form a finite number of polygons distributed in the three-dimensional space, and each polygon has the information of the normal vector of the plane where the polygon is located and the vertex of the polygon. The vertex of the polygon can determine the two-dimensional coordinate (x, y) and the height h of the three-dimensional model at the position, and the normal vector of the plane where the polygon is located can determine two angular variables (θ, φ). Therefore, the control of the emergent light can be realized through the surface morphology design of the three-dimensional model, and different 3D optical effect is thus formed.

The surface phase distribution of an ordinary spherical lens can be a superposition of multiple 2π, and different phases can cause light rays to bend to different degrees. The surface of the three-dimensional model is subjected to collapse calculation, the phase of the surface of the three-dimensional model is divided by 2π as a unit, and then collapsed, the phase of integer multiple of 2π is removed to leave a remainder, the remainder being 0-27 distribution, and finally an annulus is formed, such as the Fresnel structure formed in FIG. 11 above. The phase delay of each annulus period is 2π. Since the slopes of the inclined plane of the three-dimensional model surface are different, the period of the collapsed structure will decrease with the increase of the slope, and it will reach the machining limit when the period is small to a certain extent.

When viewed in cross-section, the surface consists of a series of zigzag prisms. The height of the zigzag prism is related to the central wavelength. Specifically, the height is

$$h = \frac{λ}{n - 1} ,$$

n being the retractive index.

When the collapsed unit height is an integer multiple of the wavelength, i.e., the collapse unit of the zigzag prism is P*2π, the widths of all the annuli after the collapse are correspondingly expanded at the same time, and the zigzag prism height is also expanded at the same time by P times.

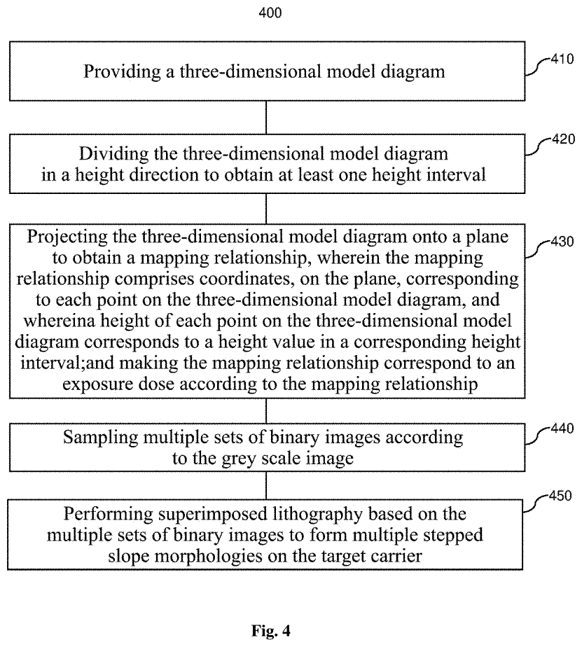

A second embodiment of a preparation method for a three-dimensional micro-nano morphological structure according to the present invention has been proposed for this reason due to the high time consumption and low efficiency of grey scale lithography. FIG. 4 is a schematic view showing a structure of a preparation method for a three-dimensional micro-nano morphological structure according to a second embodiment of the present invention. As shown in FIG. 4, the preparation method 400 for a three-dimensional micro-nano morphological structure includes the following steps.

Step 410. Providing a three-dimensional model diagram. Specifically, providing a three-dimensional model diagram includes: the three-dimensional model diagram including at least one three-dimensional model unit, setting at least one curvature value to the three-dimensional model unit, and determining the height of a point in the three-dimensional model diagram based on the curvature value.

Step 420. Dividing the three-dimensional model diagram in a height direction to obtain at least one height interval.

Step 430. Projecting the three-dimensional model diagram onto a plane to obtain a mapping relationship, wherein the mapping relationship comprises coordinates, on the plane, corresponding to each point on the three-dimensional model diagram, and wherein the height of each point on the three-dimensional model diagram corresponds to a height value in a corresponding height interval, and making the mapping relationship correspond to an exposure dose according to the mapping relationship.

In one embodiment, projecting the three-dimensional model diagram on a plane to obtain a mapping relationship further comprises: obtaining a grey scale value corresponding to the height value of each point in the mapping relationship by correlating each height interval on the three-dimensional model to a grey scale value range, and obtaining a grey scale image according to the plane coordinate and the height value in the mapping relationship. Correlating the grey graph to the exposure dose.

Step 430 is the same as step 130 in the first embodiment and is not repeated herein.

Step 440. Sampling multiple sets of binary images according to the grey scale image.

In one embodiment, sampling multiple sets of binary images according to the grey scale image includes:

sampling M−1 sets of binary images according to the number M of steps;

assigning a pixel point with a grey scale value in range 1 to be black or white, and assigning a pixel point with a grey scale value in another range to be the other, so as to obtain the first set of binary images;

assigning a pixel point with a grey scale value in range 2 to be black or white, and assigning a pixel point with a grey scale value in other ranges to be white, so as to obtain a second set of binary images; and

assigning a pixel point with a grey scale value in range M−1 to be black or white, and assigning a pixel point with a grey scale value in other ranges to be white, so as to obtain the (M−1)^{th} set of binary images;

wherein M is an integer greater than or equal to 2; and

wherein the interval of range 2 at least partially covers the interval of range 1, and the interval of range M−1 at least partially covers the interval of range M−2.

Step 450. Performing superimposed lithography based on the multiple sets of binary images to form multiple stepped slope morphologies on the target carrier.

The time consumption of grey scale lithography can be greatly reduced by using multiple sets of binary images to perform superimposed lithography.

Step 440 and step 450 may collectively constitute step 130 of performing lithography based on the exposure dose as described in the first embodiment.

Several application examples of the preparation method 400 for a three-dimensional micro-nano morphological structure are described below.

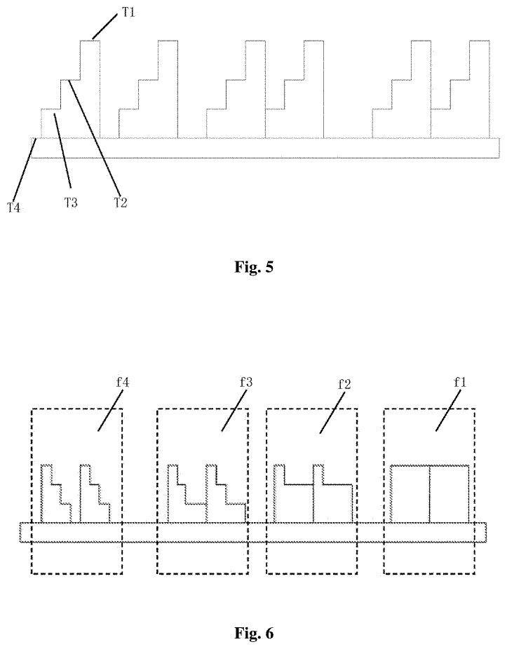

Application example 3. The height of the three-dimensional model is 3 mm and the height difference of the height interval is 20 μm. Then it is divided into a total of 3 mm/20 μm=150 height intervals. Then there are 150 sets of loop lines in the projected grey scale image, the grey range is 0-255, and the grey scale value between two loop lines in the 150 sets of loop lines varies linearly from 0 to 255. The grey scale image is divided into four steps, that is to say, it is necessary to sample three sets of binary images. Sampling the grey scale range from 0 to 31: extracting the grey image in the range, assigning the grey scale value in the range of 0-31 as 0 (or as 1), and assigning the grey scale value in other ranges as 1 (or 0) to obtain the first set of binary image. The second set of the binary image is obtained by sampling the grey scale range from 0 to 63, and the third set of the binary image is obtained by sampling the grey scale range from 0 to 127. Superimposed exposure is performed on the three sets of binary images to obtain a 4-step slope morphology, such as T1, T2, T3, and T4 shown in FIG. 5. After that, a smooth slope morphology is obtained through subsequent proceedings.

Application example 4. The height of the three-dimensional model is 3 mm and the height difference of the height interval is 20 μm. Then it is divided into a total of 3 mm/20 μm=150 height intervals. Then there are 150 sets of loop lines in the projected grey scale image. The grey scale ranges are 0-255, 0-127, 0-63, and 0-31. The corresponding grey scale value between two loop lines in the first 30-loop line set starting from the inside is from 0 to 31, the corresponding grey scale value between two loop lines in the second 30-loop line set is from 0 to 63, the corresponding grey scale value between two loop lines in the third 30-loop line set is 0-127, and the corresponding grey scale value between two loop lines in the last 60-loop line set is 0-255. The grey scale image is divided into four steps, that is to say, it is necessary to sample three sets of binary images. Sampling the grey scale range from 0-31: extracting the grey image in the range, assigning the grey scale value in the range of 0-31 as 0 (or as 1), and assigning the grey scale value in other ranges as 1 (or 0) are conducted to obtain the first set of binary image. Then the grey scale range is sampled from 0 to 63, and the grey scale range is sampled from 0 to 127 to obtain the second set of and the third set of binary images. The three sets of binary images are subjected to superimposed exposure to obtain one structure with two-step (region f2 in FIG. 6), three-step (region f3 in FIG. 6), and four-step (region f4 in FIG. 6) slope morphology. As shown in FIG. 6, region f1 corresponds to a post-lithography morphology of a loop line set having a grey scale value from 0 to 31, region f2 corresponds to a post-lithography morphology of a loop line set having a grey scale value from 0 to 63, region f3 corresponds to a post-lithography morphology of a loop line set having a grey scale value from 0 to 127, and region f4 corresponds to a post-lithography morphology of a loop line set having a grey scale value from 0 to 255. A smooth slope morphology is obtained through subsequent proceedings.

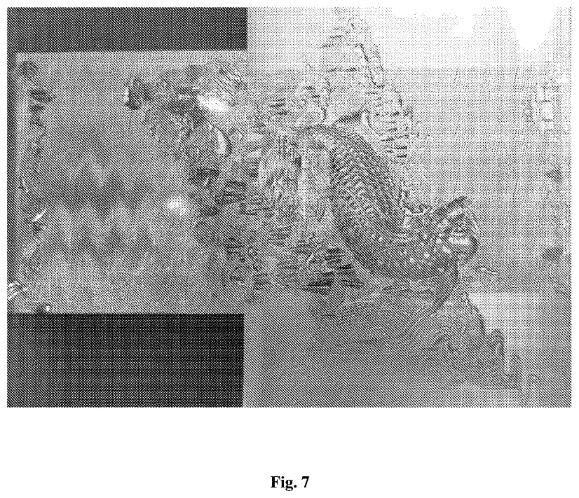

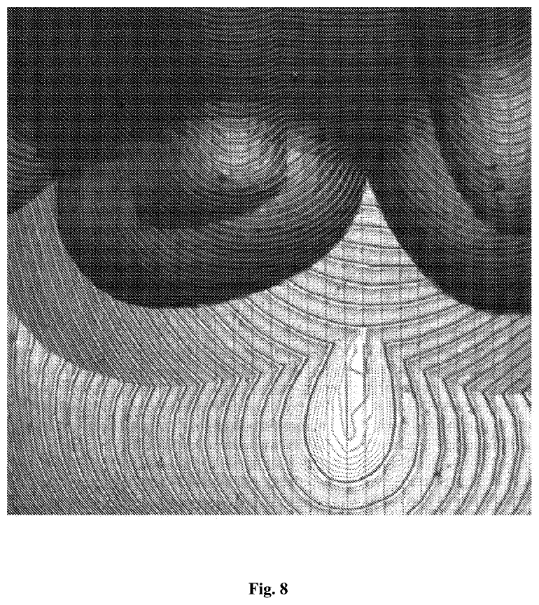

According to another aspect of the present invention, there is also provided a three-dimensional micro-nano morphology structure manufactured by a laser direct writing lithography machine. FIGS. 2c and 3 each show a partial region of a three-dimensional micro-nano morphological structure. The three-dimensional micro-nano morphological structure includes a substrate 210 and at least one three-dimensional micro-nano morphological unit formed on the substrate 210. Reference is made to FIG. 2c and FIG. 3 which schematically show only one three-dimensional micro-nano morphological unit. FIG. 7 is an example of a three-dimensional micro-nano morphological structure manufactured by a preparation method for a three-dimensional micro-nano morphological structure according to the present invention. As shown in FIG. 7, it is a dragonfish having a three-dimensional appearance. Although the dragonfish appears to be three-dimensional, in reality, the carriers carrying the dragonfish are planes. It is because the three-dimensional micro-nano morphological structure described in the present invention is formed on it so that it has a real three-dimensional effect. As shown in FIG. 7, the squamae of the dragonfish are independent three-dimensional micro-nano morphological units, and the water waves on the sides are also independent three-dimensional micro-nano morphological units. The structure of each three-dimensional micro-nano morphological unit is similar to that of FIG. 2b and FIG. 2c. In particular, each three-dimensional micro-nano morphological unit comprises at least one visual high point, and each three-dimensional micro-nano morphological unit comprises multiple strips gradually increasing in the slope of a slope morphology starting from the visual high point. The slope of the slope morphology at the visual high point is minimal. When multiple three-dimensional morphological units are included, the multiple three-dimensional morphological units are arranged in a stacked or tiled arrangement. As illustrated in FIG. 2c, the visual high point is point O, which shows three strips d1, d2, and d3. In fact, there may be hundreds of strips, at least some of which are formed with a slope morphology 221 sloping downwards, the slope morphology of each strip may be continuous, and each three-dimensional micro-nano morphological unit comprises multiple strips with gradually increasing slope of the slope morphology starting from the visual high point. In one embodiment, the depths of the slope morphology in the three-dimensional micro-nano morphological unit are the same, and the period of the slope morphology gradually decreases from the visual high point, as shown in FIG. 2c. In another embodiment, the periods of the slope morphologies are the same and the depth of the slope morphology is gradually increased, as shown in FIG. 3. In another embodiment, both the period and the depth of the slope morphology vary according to a set rule such that the slope gradually increases. In one embodiment, the period of the slope morphology is in the range of 1-100 μm, the depth of the slope morphology is in the range of 0.5-30 μm, and the included angle formed by the inclined surface of the slope morphology and the ground varies in the range of 0 degrees to 45 degrees. By such an arrangement, the three-dimensional micro-nano morphological unit can be made to have a stereoscopic vision effect, and the smaller the width of the period is, the higher the visual stereoscopic effect is.

In one embodiment, the depth of the slope morphology of at least some of the strips is different from the depth of the slope morphology of other strips. As shown in FIG. 3, the depth of the slope morphology of the strips in the e1 region is significantly different from the depth of the slope morphology of the strips in the e2 region.

In one embodiment, the strip is an annular strip. The strips may or may not have a gap therebetween. The slope morphology may be a combination of one or more of a stepped shape, a linear ramp, and a curved ramp.

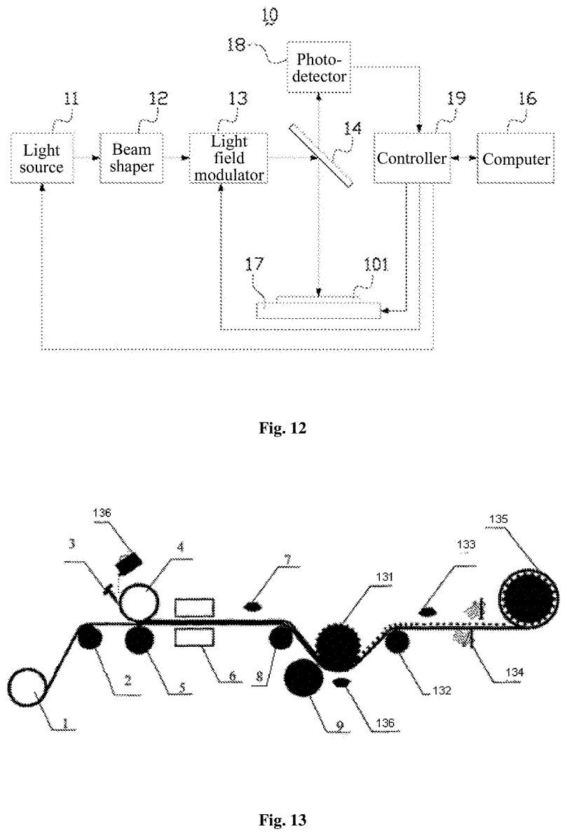

In one embodiment, the grey scale image or the sampled binary image is segmented into multiple unit images for lithography on a lithographic apparatus. As shown in FIG. 12, one embodiment of the lithographic apparatus of the present invention is shown. As shown in FIG. 12, the lithographic apparatus 10 includes a light source 11, a beam shaper 12, a light field modulator 13, a mirror 14, a computer 16, an object stage 17, a photodetector 18, and a controller 19.

The light source 11 is used to provide the laser needed for lithography. In this embodiment, the light source 11 of the lithographic apparatus 10 is a laser, but is not limited to the laser.

The beam shaper 12 serves to shape the light emitted by the light source 11. In this embodiment, the beam shaper 12 can shape the light into a flat top beam.

The light field modulator 13 is used to generate graphic light from the shaped light. In this embodiment, the light field modulator 13 may display a lithographic image such that the graphic light is generated as the shaped light passes through the light field modulator 13. The light field modulator 13 of the present invention is for example, but not limited to, a spatial light modulator or a phase light modulator.

The mirror 14 is used to reflect the graphic light to the surface of the lithography piece 101 to be exposed for direct writing lithography.

The computer 16 is used to provide lithographic images and displacement data.

The object stage 17 is used for carrying the lithography piece 101. The object stage 17 can move in two directions perpendicular to each other in a horizontal plane, so as to realize the relative movement between the photolithographic light spot and the lithography piece 101, and depict a pattern with a certain area.

The photodetector 18 is used to collect light reflected from the surface of the lithography piece 101 and to generate data representing the morphology.

The controller 19 is used to control the various components of the lithographic apparatus 10 to operate in coordination, such as data import, motion synchronization control, focus control, etc. Specifically, the controller 19 receives the lithographic image sent by the computer 16, and the controller 19 can upload the lithographic image to the light field modulator 13, and at this time, the light field modulator 13 can display the lithographic image, so that the shaped light generates graphic light when passing through the light field modulator 13. The controller 19 is also used for controlling the movement of the object stage 17, in particular, according to the displacement data sent by the computer 16, controlling the movement of the object stage 17 in a horizontal plane so as to realize the relative movement between the photolithographic light spot and the lithography piece 101 and draw a pattern with a certain area. The controller 19 is also configured to receive morphological data generated by the photodetector 18 and adjust the focal length between the phase device and the lithography piece 101 according to the morphological data. It should be noted that the controller 19 may control the turning off or turning on of the light source 11 according to the period of the exposure image. The lithographic image herein may be a grey scale image as mentioned above in the preparation method for a three-dimensional micro-nano morphological structure.

After the lithography is completed, the obtained photolithographic member 101 is subjected to metal growth to obtain a stencil. The stencil is wrapped around a printing roller for nano-imprinting, so that the three-dimensional micro-nano morphological structure as described above can be obtained on the material to be imprinted, such as a dragonfish as shown in FIG. 7. As shown in FIG. 13, one embodiment of a nano-imprinting device of the present invention is shown. As shown in FIG. 13, the nano-imprinting device includes a conveying device, a coating device, a pre-curing device, an imprinting device, a strong curing device, and a cooling device.

The conveying device at least comprises a material feeding roller 1 and a material receiving roller 135, which are located at two ends of the whole set of imprinting devices. A cylindrical convoluted material to be imprinted is placed on the material feeding roller 1, and the open end of it is wound to the material receiving roller 135. When the imprinting is started, the material feeding roller 1 and the material receiving roller 135 rotate at the same linear speed in a reverse direction of the material winding, so that the material to be imprinted is conveyed along a specified route. The conveying device also comprises auxiliary rollers 2, 8, and 132, each being located over the entire conveying route respectively. The auxiliary rollers allow the material to be constantly under tension as it passes through various processes.

The coating device is provided after the material feeding roller 1. The coating device comprises a scraper 3, an anilox roller 4, a lining roller 5, and a dispenser machine 136. The dispenser machine 136 is provided with a liquid UV adhesive therein, which can move along the axial direction of the anilox roller 4 to uniformly coat the UV adhesive on the surface of the anilox roller 4. The surface of the anilox roller 4 has a concave-convex anilox graphic pattern, the UV adhesive is absorbed in the anilox, and the adhesive carrying amount of the UV adhesive is controlled by adjusting the mesh number of the anilox. The scraper 3 acts on the anilox roller 4 to scrape off excess adhesive coated on the anilox roller 4. The lining roller 5 is provided on the opposite sides of the anilox roller 4 and cooperates with the anilox roller 4 to apply UV adhesive to the surface of the material. By controlling the mesh number of the anilox on the anilox roller 4, the distance of the scraper 3 from the anilox roller 4, and the pressing pressure of the lining roller 5 against the anilox roller 4, the coating device described above can achieve a coating thickness of the UV adhesive controlled in the range of 2-50 μm to accommodate the imprinting requirements for nano-level graphic patterns.

After a coating device there is also provided a pre-curing device comprising a levelling-and-drying tunnel 6 and an ultraviolet pre-curing apparatus 7. The UV adhesive layer will appear uneven distribution on the surface when it is coated, while nano imprinting is quite demanding for flatness. In order to eliminate the unevenness of the surface, the raw material with the UV adhesive is made to pass through the levelling-and-drying tunnel 6 to be levelled by the gravity of the liquid itself, and the UV adhesive is heated by an infrared heating device or a resistance heating device, so as to volatilize the water or alcohol, etc. contained therein, thereby preserving the levelled surface flatness. The UV adhesive is then pre-cured by means of an ultraviolet pre-curing apparatus 7. The ultraviolet pre-curing apparatus 7 is such as a low-power UV lamp, which makes the originally liquid UV adhesive semi-solid for imprinting.

An imprinting device is arranged after the pre-curing device and comprises at least a pressure roller 9 and a printing roller 131. The surface of the printing roller 131 is provided with a graphic pattern of a nanostructure, the stencil being mounted on the surface of the printing roller 131. The printing roller 131 is brought into intimate contact with the above-mentioned semi-solid UV adhesive in cooperation with the pressure roller 9, and then irradiated by an ultraviolet lamp 136 so that the graphic pattern on the UV adhesive is formed before being separated from the printing roller 131. The pressure control system of the pressure roller 9 may use hydraulic control or pneumatic control. It needs to be noted that the printing roller 131 may be made by applying a stencil provided with a desired graphic pattern on the surface, or a desired nano graphic pattern may be directly made on the surface of the printing roller, and the material of the stencil or the printing roller may be nickel, aluminum, etc.

Finally, the UV adhesive on which the nano graphic pattern has been printed is hardened, shaped, and cooled by the strong curing device 133 and the cooling device 134, and a formed product is received through the material receiving roller 135. The strong curing device 133 includes at least one set of high-power UV lamps, and the cooling device 134 may be an air-cooling device or a water-cooling device.

A specific imprinting process of the nano-imprinting device is as follows:

Firstly, a cylindrical convoluted material to be imprinted is arranged on the material feeding roller, an open end of the material is wound on the material receiving roller, and the material feeding roller and the material receiving roller are rotated at the same speed so that the material to be imprinted is conveyed along a specified route;

After feeding the material, the coating device is used to uniformly coat the UV adhesive on the raw materials to be imprinted;

Then the pre-curing device is used to perform leveling, heating and ultraviolet pre-curing on the coated UV adhesive so that the UV adhesive is flat and assumes a semi-solid state;

Subsequently, the imprinting device is used to imprint the UV-adhesive-coated material, so that the graphic pattern of a nanostructure on the printing roller is imprinted onto the UV adhesive;

Finally, the UV adhesive is formed and cured by the strong curing device, and the formed product is received to the material receiving roller 135.

The position and the tension of the material can also be adjusted in real-time throughout the entire imprinting process by means of a deviation correction system and a tension control system so as to ensure the quality of the imprinting.

In the present invention, the material to be imprinted may be rolled materials made of such as Polycarbonate (PC), Polyvinylchloride (PVC), Polyester (PET), Polymethyl Methacrylate (PMMA), or Biaxially Oriented Polypropylene (BOPP).

As used herein, the terms “comprise”, “comprising”, or any other variation thereof, are intended to cover a non-exclusive inclusion. In addition to those elements listed, other elements not explicitly listed can also be included.

In this document, the terms “front”, “back”, “up”, “down”, etc. are defined by the positions of parts and components in the drawings and positions between the parts and components, only for the sake of clarity and convenience in the technical solutions. It should be understood that the use of directional terms should not limit the scope of the present application.

The features of the embodiments and embodiments described herein may be combined with one another without conflict.

The above is only a preferred embodiment of the present invention and is not intended to limit the present invention. Any modification, equivalent replacement, improvement, etc. made within the spirit and principle of the invention shall be included in the scope of the invention.

What is claimed is:

1. A preparation method for a three-dimensional micro-nano morphological structure manufactured by a laser direct writing lithography machine, comprising:
providing a three-dimensional model diagram;
dividing the three-dimensional model diagram in a height direction to obtain at least one height interval; and
projecting the three-dimensional model diagram onto a plane to obtain a mapping relationship, wherein the mapping relationship comprises coordinates, on the plane, corresponding to each point on the three-dimensional model diagram, and wherein a height of each point on the three-dimensional model diagram corresponds to a height value in a corresponding height interval; and making the mapping relationship correspond to an exposure dose according to the mapping relationship, and performing lithography on the basis of the exposure dose.

2. The preparation method according to claim 1, wherein providing a three-dimensional model diagram comprises:
the three-dimensional model diagram comprising at least one three-dimensional model unit, and setting at least one curvature value to the three-dimensional model unit.

3. The preparation method according to claim 1, wherein providing a three-dimensional model diagram comprises:
fitting a surface of the three-dimensional model diagram by splicing multiple spatial polygons, wherein each of the spatial polygons is a convex polygon, each of the spatial polygons does not overlap with each other, each of the spatial polygons has a determined vertex and side, and a height range of the three-dimensional model diagram at a polygon position is determined according to the vertex of the spatial polygon and a normal vector of the plane where the spatial polygon is located.

4. The preparation method according to claim 1, wherein each height interval has a same height difference or each height interval has a different height difference.

5. The preparation method according to claim 1, wherein projecting the three-dimensional model diagram on a plane to obtain a mapping relationship further comprises:
obtaining a grey scale value corresponding to the height value of each point in the mapping relationship by correlating each height interval on the three-dimensional model to a grey scale value range, and obtaining a grey scale image according to a plane coordinate and the height value in the mapping relationship.

6. The preparation method according to claim 5, wherein a height range of each height interval corresponds linearly or curvilinearly to one grey scale value range.

7. The preparation method according to claim 5, wherein performing lithography based on the exposure dose comprises:
sampling multiple sets of binary images according to the grey scale image; and
performing superimposed lithography based on the multiple sets of binary images to form multiple stepped slope morphologies on a target carrier.

8. The preparation method according to claim 7, wherein sampling multiple sets of binary images according to the grey scale image comprises:
sampling M−1 sets of binary images according to the step number M;
assigning a pixel point with a grey scale value in range 1 to be black or white, and assigning a pixel point with a grey scale value in another range to be the other, so as to obtain a first set of binary images;
assigning a pixel point with a grey scale value in range 2 to be black or white, and assigning a pixel point with a grey scale value in other ranges to be white, so as to obtain a second set of binary images;
and assigning a pixel point with a grey scale value in range M−1 to be black or white, and assigning a pixel point with a grey scale value in other ranges to be white, so as to obtain an (M−1)^{th} set of binary images;
wherein M is an integer greater than or equal to 2; and
wherein an interval of range 2 at least partially covers the interval of range 1, and the interval of range M−1 at least partially covers the interval of range M−2.

9. The preparation method according to claim 5, wherein performing lithography based on the exposure dose comprises:
segmenting the grey scale image into multiple unit images followed by lithography to form a preset smooth slope morphology on a target carrier.

10. A three-dimensional micro-nano morphological structure manufactured by a laser direct writing lithography machine, comprising:
a substrate; and
at least one three-dimensional micro-nano morphological unit formed on the substrate,
wherein each three-dimensional micro-nano morphological unit comprises at least one visual high point, and each three-dimensional micro-nano morphological unit comprises multiple annuli, wherein a slope of a slope morphology in the annuli changes according to a preset rule starting from a visual high point.

11. The three-dimensional micro-nano morphological structure according to claim 10, wherein depths of the slope morphology in the three-dimensional micro-nano morphological unit are the same, and a period of the slope morphology gradually decreases from the visual high point; or periods of slope morphologies are the same, and the depth of slope morphology gradually increases from the visual high point; or both the period and the depth of the slope morphology vary according to a set rule, so that the slope gradually increases from the visual high point.

12. The three-dimensional micro-nano morphological structure according to claim 11, wherein the period of the slope morphology is in a range of 1-100 μm, the depth of the slope morphology is in the range of 0.5-30 μm, and an included angle formed by an inclined plane of the slope morphology and a plane varies in the range from 0-45 degrees.

13. The three-dimensional micro-nano morphological structure according to claim 10, wherein the slope of the slope morphology at the visual high point is minimal, and multiple three-dimensional morphological units are arranged to be in a stack or tiled.

14. The three-dimensional micro-nano morphological structure according to claim 10, wherein the slope morphology is a combination of one or more of a stepped shape, a linear ramp, and a curved ramp.
